(19) United States
(12) Patent Application Publication
(10) Pub. No.: US 2014/0103365 A1
(43) Pub. Date: Apr. 17, 2014

(54) SEMICONDUCTOR DEVICE AND METHOD FOR MANUFACTURING SAME

(71) Applicant: Sumitomo Electric Industries, Ltd., Osaka-shi (JP)

(72) Inventors: Kazunori Fujimoto, Osaka-shi (JP); Taku Horii, Osaka-shi (JP); Shinji Kimura, Kawasaki-shi (JP); Mitsuo Kimoto, Itami-shi (JP)

(73) Assignee: Sumitomo Electric Industries, Ltd., Osaka-shi (JP)

(21) Appl. No.: 14/052,467

(22) Filed: Oct. 11, 2013

Related U.S. Application Data
(60) Provisional application No. 61/714,022, filed on Oct. 15, 2012.

(30) Foreign Application Priority Data
Oct. 15, 2012 (JP) 2012-227653

(51) Int. Cl. H01L 29/16

(52) U.S. Cl. CPC H01L 29/1608
USPC 257/77; 438/285

(57) ABSTRACT

A semiconductor device includes: a substrate made of silicon carbide; an insulating film formed on a surface of the substrate; a buffer film containing no Al; and an electrode containing Al. The substrate has an electrically conductive region. In the semiconductor device, a contact hole is formed above the electrically conductive region so as to extend through the insulating film and expose the surface of the substrate. The buffer film extends upward on a side wall surface of the contact hole from a bottom surface of the contact hole. The electrode is formed in contact with the electrically conductive region on the bottom surface of the contact hole, and is formed on the insulating film with the buffer film being interposed therebetween.

### BACKGROUND OF THE INVENTION

1. Field of the Invention

The present invention relates to a semiconductor device and a method for manufacturing the semiconductor device, in particular, a semiconductor device having a stable property attained by suppressing a reaction between an electrode containing aluminum and an interlayer insulating film, as well as a method for manufacturing such a semiconductor device.

2. Description of the Background Art

As a material of a substrate for a semiconductor device capable of handling a large amount of electric power, silicon carbide (SiC) has been employed. In the case where SiC is employed as a material for a semiconductor device, a material containing aluminum (Al) has been reviewed as an electrode material that can form an ohmic junction with an n type region or a p type region at a low contact resistance.

Here, in order to make ohmic contact between the electrode containing Al and each of the n type region and the p type region in the semiconductor device having the substrate made of SiC, it is necessary to perform alloying treatment at a high temperature such as approximately 1000° C. after forming the electrode on each of the regions, for example.

Meanwhile, in a MOSFET (Metal Oxide Semiconductor Field Effect Transistor), a positional relation or the like has been reviewed among such a source electrode containing Al, a gate electrode, a gate insulating film, and an interlayer insulating film (for example, see U.S. Pat. No. 6,833,562 and Japanese Patent Laying-Open No. 2000-012846), for example. As an another example, in a MOSFET, a source electrode may be formed on and in contact with a surface of a substrate having an active region formed therein, and in contact with a side wall surface of an interlayer insulating film made of silicon dioxide (SiO₂) and formed to surround the gate electrode on the surface.

### SUMMARY OF THE INVENTION

However, generally, when heating treatment is performed at a temperature of approximately 500° C. or more in the case where the source electrode containing Al and the interlayer insulating film made of SiO₂ are in contact with each other, SiO₂ is reduced to Si by alloyed Al. Accordingly, electric properties such as the insulating property and capacitance stability of the interlayer insulating film may be deteriorated.

The present invention has been made to solve the foregoing problem. The present invention has a main object to provide a semiconductor device configured to be capable of suppressing a reaction between Al and SiO₂, as well as a method for manufacturing such a semiconductor device.

A semiconductor device of the present invention includes: a substrate made of silicon carbide; an insulating film formed on a surface of the substrate; a buffer film containing no Al; and an electrode containing Al. The substrate has an electrically conductive region. In the semiconductor device, a contact hole is formed above the electrically conductive region so as to extend through the insulating film and expose the surface of the substrate. The buffer film extends upward on a side wall surface of the contact hole from a bottom surface of the contact hole. The electrode is formed in contact with the electrically conductive region on the bottom surface of the contact hole, the electrode being formed on the insulating film with the buffer film being interposed therebetween.

Accordingly, the electrode containing Al is formed on the insulating film containing SiO₂ with the buffer film, which contains no Al, being interposed therebetween. Hence, a reaction between Al contained in the electrode and SiO₂ contained in the insulating film can be suppressed.

Here, the expression “buffer film containing no Al” is intended to indicate a buffer film containing substantially no Al. Specifically, the buffer film is intended to indicate a buffer film in which Al is not added intentionally, and include a buffer film in which Al is contained as an inevitable impurity, for example.

The buffer film may extend onto an upper surface of the insulating film via the side wall surface. On this occasion, the buffer film may have an end portion formed on the upper surface of the insulating film. Further, the electrode may have an end portion formed on the insulating film so as to be closer to the contact hole relative to the end portion of the buffer film. Accordingly, a reaction between Al contained in the electrode and SiO₂ contained in the insulating film can be suppressed.

In the semiconductor device, a plurality of the contact holes may be formed. On this occasion, the buffer film may extend from the bottom surface of one of the plurality of the contact holes to the bottom surface of another one of the plurality of the contact holes via an upper surface of the insulating film so as to cover a portion of the insulating film between adjacent ones of the plurality of the contact holes. Accordingly, at the portion of the insulating film between the adjacent ones of the plurality of the contact holes, a reaction between Al contained in the electrode and SiO₂ contained in the insulating film can be suppressed.

In the semiconductor device, the electrode on the insulating film may be formed to cover an entire surface of the buffer film. Further, in the semiconductor device, the electrode on the insulating film may be formed to cover a portion of the buffer film. Thus, when the buffer film extends to cover the insulating film, a reaction between Al and SiO₂ can be suppressed irrespective of the pattern shape of the electrode.

According to the present invention, there can be provided a semiconductor device capable of suppressing a reaction between aluminum contained in an electrode and silicon dioxide contained in an insulating film, as well as a method for manufacturing such a semiconductor device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view of a semiconductor device according to a first embodiment.

FIG. 2 is a partial cross sectional view of a semiconductor device according to a second embodiment.

FIG. 3 shows a modification of FIG. 2.

FIG. 4 is a partial cross sectional view of a semiconductor device according to a third embodiment.

FIG. 5 is a flowchart showing a method for manufacturing the semiconductor device according to the first embodiment.

FIG. 6 is a flowchart showing an ohmic electrode forming step in the method for manufacturing the semiconductor device according to the first embodiment.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly.

### First Embodiment

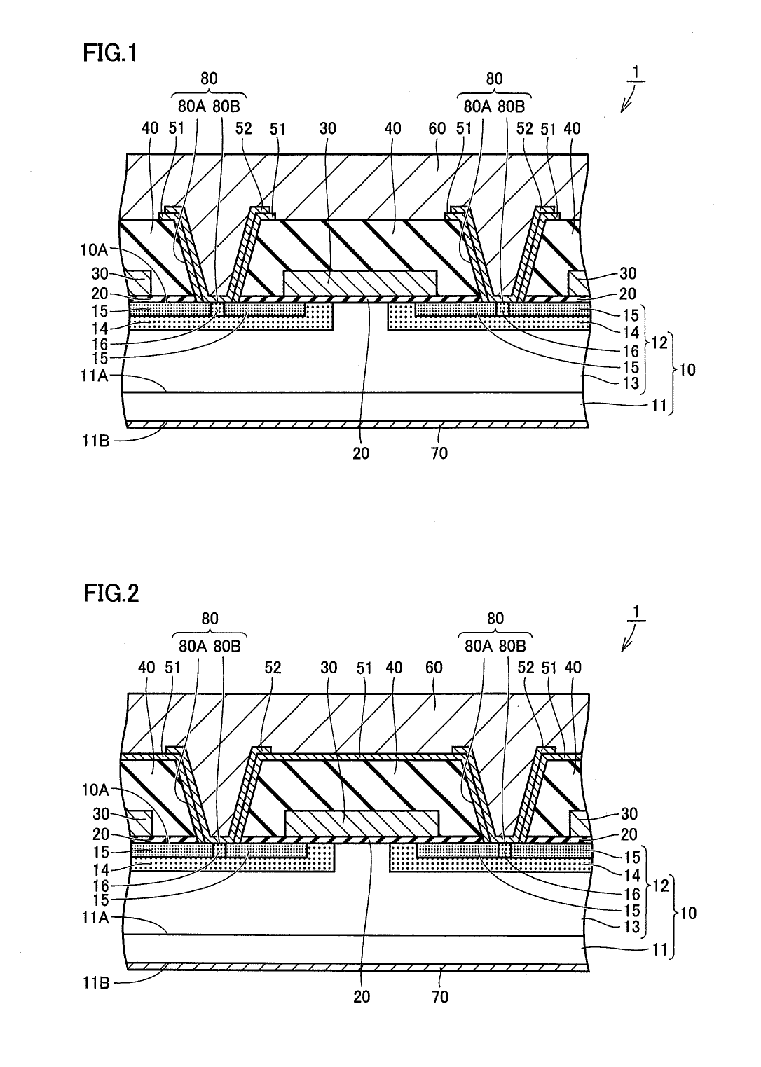

First, the following describes a structure of a MOSFET 1 serving as a semiconductor device according to the present embodiment. Referring to FIG. 1, MOSFET 1 includes a substrate 10 made of silicon carbide, gate insulating films 20, gate electrodes 30, interlayer insulating films 40, buffer films 51, source electrodes 52, a source interconnection 60, and a drain electrode 70. Substrate 10 includes a base substrate 11 and a semiconductor layer (electrically conductive region) 12. In semiconductor layer 12, a drift region 13, body regions 14, source regions 15, and contact regions 16 are formed. Further, in MOSFET 1, contact holes 80 are formed to be separated from gate electrodes 30, extend through gate insulating film 20 and interlayer insulating film 40, and expose a main surface 10A of substrate 10.

Base substrate 11 contains an n type impurity such as N (nitrogen) and therefore has n type conductivity (first conductivity type). Drift region 13 is an epitaxial growth layer formed on a main surface 11A of base substrate 11. As with base substrate 11, drift region 13 contains an n type impurity such as N (nitrogen), and therefore has n type conductivity. The concentration thereof in drift region 13 is lower than that in base substrate 11.

Body regions 14 include main surface 10A of substrate 10, and are formed to be separated from each other in semiconductor layer 12. Each of body regions 14 contains a p type impurity such as Al (aluminum) or B (boron), and therefore has p type conductivity (second conductivity type).

Source regions 15 include main surface 10A, and are formed in body regions 14 such that they are surrounded by body regions 14. Each of source regions 15 contains an n type impurity such as P (phosphorus), and therefore has n type conductivity as with base substrate 11 and drift region 13. Further, the concentration of the n type impurity in source region 15 is higher than the concentration of the n type impurity in drift region 13.

As with source region 15, contact regions 16 include main surface 10A, are surrounded by body regions 14, and are respectively formed in body regions 14 so as to be adjacent to source regions 15. As with body region 14, each of contact regions 16 contains a p type impurity such as Al (aluminum) or B (boron) and therefore has p type conductivity. The concentration thereof in contact region 16 is higher than that in body region 14.

Each of gate insulating films 20 contains SiO₂ (silicon dioxide), is formed to be disposed on and in contact with main surface 10A, and extend from the upper surface of one source region 15 to the upper surface of the other source region 15.

Each of gate electrodes 30 is disposed on and in contact with gate insulating film 20, and is formed to extend from one source region 15 onto the other source region 15. Gate electrode 30 is made of a conductor such as polysilicon having an impurity added therein, for example.

Interlayer insulating film 40 contains SiO₂ (silicon dioxide), and is formed on gate insulating film 20 to surround gate electrode 30.

Each of contact holes 80 has side wall surfaces 80A and a bottom surface 80B, and is formed to extend through interlayer insulating film 40 and gate insulating film 20. Further, as shown in FIG. 1, each of side wall surfaces 80A of contact hole 80 is constituted of interlayer insulating film 40 and gate insulating film 20, and bottom surface 80B thereof corresponds to the upper surfaces of source region 15 and contact region 16.

Buffer film 51 extends upward on side wall surface 80A of contact hole 80 from bottom surface 80B. Moreover, buffer film 51 extends onto upper surface 40A of interlayer insulating film 40 via side wall surface 80A. Here, buffer film 51 is formed in contact with side wall surface 80A and upper surface 40A. Further, the buffer film has an end portion 51A formed on upper surface 40A of interlayer insulating film 40. Buffer film 51 is a film that does not contain Al and SiO₂, for example, may be a film made of titanium nitride (TiN), titanium tungsten (TiW), tantalum nitride (TaN), or the like.

Source electrode 52 is formed on and in contact with buffer film 51 and main surface 10A of substrate 10 exposed by forming contact hole 80. Further, source electrode 52 is formed on interlayer insulating film 40 and gate insulating film 20 with buffer film 51 being interposed therebetween. Namely, source electrode 52 is not in contact with interlayer insulating film 40 and gate insulating film 20 on side wall surface 80A of contact hole 80 and upper surface 40A of interlayer insulating film 40. Source electrode 52 has an end portion 52A formed to be closer to the contact hole relative to end portion 51A of buffer film 51. Source electrode 52 is a film containing Al, for example, may be made of a TiAlSi alloy.

Drain electrode 70 is formed on a main surface 11B of base substrate 11 opposite to main surface 11A thereof. As with source electrode 52, drain electrode 70 is made of, for example, a TiAlSi alloy, and is electrically connected to base substrate 11.

Source interconnection 60 is formed to cover source electrode 52 and interlayer insulating film 40. Source interconnection 60 is made of a metal such as Al (aluminum), and is electrically connected to source region 15 via source electrode 52.

The following describes an operation of MOSFET 1 serving as the semiconductor device according to the present embodiment. Referring to FIG. 1, when a voltage is applied between source electrode 52 and drain electrode 70 while an applied voltage to gate electrode 30 is lower than a threshold voltage, i.e., while it is in OFF state, a pn junction formed between body region 14 and drift region 13 is reverse-biased. Accordingly, MOSFET 1 is in the non-conductive state. Meanwhile, when gate electrode 30 is fed with a voltage equal to or more than the threshold voltage, an inversion layer is formed in body region 14. As a result, source region 15 and drift region 13 are electrically connected to each other, whereby a current flows between source electrode 52 and drain electrode 70. In the manner described above, MOSFET 1 operates.

As described above, in MOSFET 1 of the present embodiment, source electrode 52 is formed on side wall surface 80A of contact hole 80, which extends through interlayer insulating film 40 and gate insulating film 20, and upper surface 40A of interlayer insulating film 40 with the buffer film being interposed therebetween. Accordingly, source electrode 52 and interlayer insulating film 40 are not in contact with each other, thereby suppressing a reaction between Al contained in source electrode 52 and SiO₂ of interlayer insulating film 40.

Further, in the present embodiment, end portion 52A of source electrode 52 is formed on upper surface 40A of interlayer insulating film 40 so as to be closer to contact hole 80 relative to end portion 51A of buffer film 51. Accordingly, even when Al is migrated due to high temperature treatment such as alloying treatment after forming source electrode 52, buffer film 51 provides a longer distance in which Al is migrated from end portion 52A of source electrode 52 to interlayer insulating film 40. As a result, a reaction between Al contained in source electrode 52 and SiO₂ of interlayer insulating film 40 can be suppressed in the high temperature treatment after forming source electrode 52.

Further, in MOSFET 1 serving as the semiconductor device according to the present embodiment, buffer film 51 may have a thickness of not less than 0.025 μm and not more than 0.15 μm. In this way, adhesion between source electrode 52 and interlayer insulating film 40 can be more improved.

Further, in MOSFET 1 serving as the semiconductor device according to the present embodiment, gate insulating film 20 may not contain SiO₂. For example, gate insulating film 20 may be made of Si₃N₄.

The following describes a method for manufacturing the semiconductor device according to the present embodiment with reference to FIG. 5. In the method for manufacturing the semiconductor device in the present embodiment, MOSFET 1 serving as the semiconductor device according to the present embodiment is manufactured. Referring to FIG. 5, a substrate preparing step (S10) is first performed. In this step (S10), steps (S11) to (S14) described below are performed to prepare substrate 10 made of silicon carbide.

First, as step (S11), a base substrate preparing step is performed. In this step (S11), an ingot made of, for example, 4H—SiC is sliced to prepare base substrate 11 having n type conductivity.

Next, as step (S12), an epitaxial growth layer forming step is performed. In this step (S12), semiconductor layer 12 having n type conductivity is formed by epitaxial growth on main surface 11A of base substrate 11.

Next, as step (S13), an ion implantation step is performed. In this step (S13), for example, Al ions are first implanted into regions including main surface 10A of substrate 10, thereby forming body regions 14 of p type conductivity in semiconductor layer 12. Next, for example, P ions are implanted into each of body regions 14 at a depth shallower than the depth in which the Al ions have been implanted, thereby forming source region 15 of n type conductivity. Then, for example, Al ions are further implanted into body region 14, thereby forming contact region 16 adjacent to source region 15, having the same depth as that of source region 15, and having p type conductivity. Further, in semiconductor layer 12, a region in which none of body region 14, source region 15, and contact region 16 is formed serves as drift region 13.

Next, as step (S14), an activation annealing step is performed. In this step (S14), by heating substrate 10, the impurities introduced in step (S13) are activated. Accordingly, desired carriers are generated in the regions having the impurities implanted therein. In this way, by performing steps (S11) to (S14), substrate 10 is prepared in which an active region is formed by the introduction of the impurities.

Next, as a step (S20), a gate insulating film forming step is performed. In this step (S20), for example, by heating substrate 10 in an atmosphere containing oxygen, gate insulating film 20 made of SiO₂ (silicon dioxide) is formed to cover main surface 10A of substrate 10.

Next, as a step (S30), a gate electrode forming step is performed. In this step (S30), for example, an LPCVD (Low Pressure Chemical Vapor Deposition) method is employed to form, on gate insulating film 20, gate electrode 30 made of polysilicon containing an impurity.

Next, as a step (S40), an interlayer insulating film forming step is performed. In this step (S40), for example, a P (Plasma)-CVD method is employed to form interlayer insulating film 40 made of SiO₂ (silicon dioxide) on gate insulating film 20 such that interlayer insulating film 40 and gate insulating film 20 surround gate electrode 30.

Next, as a step (S50), a contact hole forming step is performed. In this step (S50), contact hole 80 is formed to have side wall surface 80A and bottom surface 80B and expose main surface 10A of substrate 10. Specifically, for example, an etching method such as RIE (Reactive Ion Etching) is employed to etch through interlayer insulating film 40 and gate insulating film 20, thereby forming contact hole 80 exposing main surface 10A of substrate 10 (the upper surfaces of source region 15 and contact region 16). Further, in this step (S50), contact hole 80 is formed to be separated from gate electrode 30. Hence, gate electrode 30 is maintained to be surrounded by gate insulating film 20 and interlayer insulating film 40.

Next, as a step (S60), a buffer film forming step is performed. In this step (S60), for example, sputtering is performed to form buffer film 51 on and in contact with bottom surface 80B and side wall surface 80A of contact hole 80 and upper surface 40A of interlayer insulating film 40. In this step (S60), for example, a film made of TiN may be formed as buffer film 51 containing no Al. Alternatively, as buffer film 51, a film made of TiW or a film made of TaN may be formed. Further, in this step (S60), buffer film 51 may be formed to have a thickness of not less than 0.025 μm and not more than 0.15 μm.

Next, as a step (S70), an etching step is performed. In this step (S70), buffer film 51 is processed to extend from bottom surface 80B of contact hole 80 onto upper surface 40A of interlayer insulating film 40 via side wall surface 80A of contact hole 80. Specifically, a resist pattern is formed on a region in which buffer film 51 will remain, and dry etching is performed from the main surface 10A side of substrate 10 using this resist pattern as a mask. This removes the portions of buffer film 51 on upper surface 40A of interlayer insulating film 40 and bottom surface 80B of contact hole 80, whereby buffer film 51 is formed to extend upward on side wall surface 80A from bottom surface 80B onto upper surface 40A of interlayer insulating film 40. Buffer film 51 has end portion 51A formed on upper surface 40A of insulating film 40. On this occasion, in contact hole 80, main surface 10A of substrate 10 (upper surfaces of source region 15 and contact region 16) is exposed again.

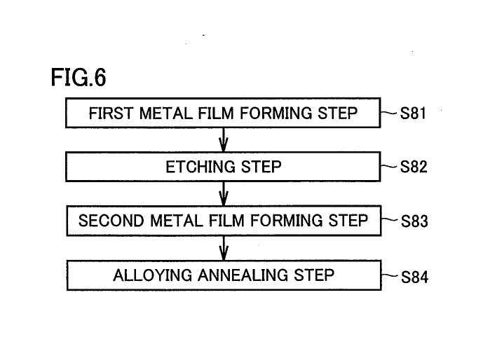

Next, as a step (S80), an ohmic electrode forming step is performed. In this step (S80), referring to FIG. 6, steps (S81) to (S84) described below are performed to form source electrode 52, which contains Ti, Al, and Si, on and in contact with buffer layer 51 and main surface 10A of substrate 10 exposed by forming contact hole 80, and form drain electrode 70, which is made of, for example, the same material as that of source electrode 52, on and in contact with main surface 11B of base substrate 11.

First, as a step (S81), a first metal film forming step is performed. In this step (S81), for example, sputtering is performed to form a first metal film structured to include a first metal layer, a second metal layer, and a third metal layer stacked on one another. The first metal layer contains Ti. The second metal layer is on and in contact with the first metal layer and contains Al. The third metal layer is on and in contact with the second metal layer and contains Si. Although the first metal film may be formed by forming the first to third metal layers on one another in this step (S81) as described above, the present invention is not limited to this. For example, a first metal film in which Ti, Al, and Si are mixed may be formed by simultaneously sputtering Ti, Al, and Si.

Next, as a step (S82), an etching step is performed. In this step (S82), a mask (not shown) is disposed in the vicinity of contact hole 80, and then dry etching is performed from the main surface 10A side of substrate 10, thereby mainly removing the first metal film formed on interlayer insulating film 40 with buffer film 51 being not interposed therebetween. Further, on the upper surface of interlayer insulating film 40, the end portion of the first metal film is formed to be closer to contact hole 80 relative to end portion 51A of buffer film 51. As a result, the first metal film is formed on side wall surface 80A and bottom surface 80B of contact hole 80 and upper surface 40A of insulating film 40 with buffer film 51 being interposed therebetween.

Next, as a step (S83), a second metal film forming step is performed. In this step (S83), as with the first metal film, a second metal film in which layers of Ti, Al, and Si are stacked on one another or in which Ti, Al, and Si are mixed is formed by means of sputtering on main surface 11B of base substrate 11, for example.

Next, as a step (S84), an alloying annealing step is performed. In this step (S84), the first and second metal films formed in steps (S81) and (S83) are heated. Accordingly, Ti, Al, and Si, which composes the first and second metal films, are alloyed, thereby forming source electrode 52 and drain electrode 70 each made of the TiAlSi alloy and making ohmic contact with substrate 10. In step (S80), by thus performing steps (S81), (S82) and (S84), source electrode 52 is formed. By performing steps (S83) and (S84), drain electrode 70 is performed. The annealing temperature may be, for example, approximately 1000° C.

Next, as a step (S90), an interconnection forming step is performed. In this step (S90), for example, a deposition method is employed to form source interconnection 60, which is made of a conductor such as Al, on and in contact with source electrode 52. By performing steps (S10) to (S90), MOSFET 1 is manufactured, thus completing the method for manufacturing the semiconductor device in the present embodiment.

As described above, in the method for manufacturing the semiconductor device in the present embodiment, buffer film 51 containing Ti and N and containing no Al is formed on and in contact with side wall surface 80A of contact hole 80 extending through interlayer insulating film 40, and thereafter source electrode 52 containing Ti, Al, and Si is formed on and in contact with buffer film 51. Thus, in the method for manufacturing the semiconductor device according to the present embodiment, buffer film 51 containing no Al is formed in advance before forming source electrode 52 containing Al. Accordingly, a reaction between Al contained in source electrode 52 and SiO₂ contained in interlayer insulating film 40 can be suppressed. Further, in the method for manufacturing the semiconductor device according to the present embodiment, end portion 52A of source electrode 52 on upper surface 40A of interlayer insulating film 40 is formed to be closer to contact hole 80 relative to end portion 51A of buffer film 51. Accordingly, even when Al contained in source electrode 52 is migrated due to alloying annealing after forming source electrode 52, buffer film 51 provides a longer distance in which Al is migrated from end portion 52A of source electrode 52 to interlayer insulating film 40. As a result, a reaction between Al contained in source electrode 52 and SiO₂ of interlayer insulating film 40 can be suppressed even when the alloying annealing is performed after forming source electrode 52.

Hence, according to the method for manufacturing the semiconductor device in the present embodiment, there can be manufactured MOSFET 1 that serves as a semiconductor device according to the present embodiment and that has a stable property attained by suppressing a reaction between source electrode 52, which is an electrode containing aluminum, and interlayer insulating film 40 containing silicon dioxide.

### Second Embodiment

Referring to FIG. 2, the following describes a semiconductor device and a method for manufacturing the semiconductor device in a second embodiment of the present invention. The semiconductor device according to the present embodiment has basically the same configuration as that of the semiconductor device according to the first embodiment, but is different therefrom in that a buffer film 51 is formed to cover a portion of interlayer insulating film 40 between adjacent ones of a plurality of contact holes 80. In MOSFET 1 serving as the semiconductor device according to the present embodiment, the plurality of contact holes 80 are formed. Buffer film 51 extends from bottom surface 80B of one of the plurality of contact holes 80 to bottom surface 80B of another one of the plurality of contact holes 80 via upper surface 40A of interlayer insulating film 40. In other words, no end portion of buffer film 51 is formed on upper surface 40A of interlayer insulating film 40.

As with the first embodiment described above, source electrode 52 is formed on and in contact with buffer film 51 and main surface 10A of substrate 10 exposed by forming contact hole 80. Further, source electrode 52 is formed to cover a portion of buffer film 51 on interlayer insulating film 40.

Accordingly, at interlayer insulating film 40 between the adjacent ones of the plurality of contact holes 80, side wall surface 80A of contact hole 80 and upper surface 40A of interlayer insulating film 40 are covered with buffer film 51 after the buffer film forming step. In the step of forming source electrode 52 as well as the alloying annealing step, SiO₂ contained in interlayer insulating film 40 and gate insulating film 20 is not exposed, so that Al contained in source electrode 52 and SiO₂ are more securely suppressed from being brought into contact and reacting with each other. In the case where buffer film 51 is made of a material having electric conductivity, buffer film 51 is electrically connected to source region 15 via source electrode 52.

The following describes a method for manufacturing the semiconductor device according to the present embodiment. The method for manufacturing the semiconductor device according to the present embodiment includes the basically the same steps as those in the first embodiment, but is different therefrom in that in step (S70) of etching the buffer film, buffer film 51 is left on upper surface 40A of interlayer insulating film 40. Accordingly, in ohmic electrode forming step (S80) performed after step (S70), interlayer insulating film 40 interposed between the adjacent ones of the plurality of contact holes 80 is covered with buffer film 51 and is therefore not exposed. Accordingly, even when Al contained in source electrode 52 is migrated in alloying annealing step (S84), a reaction between Al and SiO₂ can be suppressed.

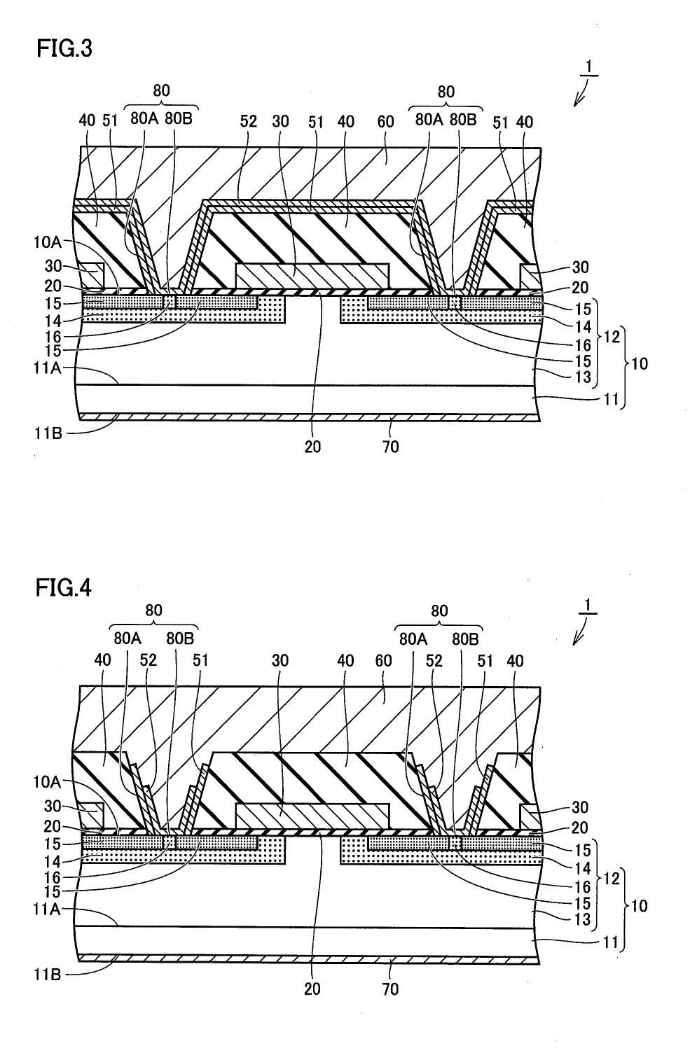

Further, in the present embodiment, source electrode 52 may be configured to have any shape on interlayer insulating film 40. In the present embodiment, no end portion of buffer film 51 is formed on interlayer insulating film 40, so that the configuration of source electrode 52 is not limited by buffer film 51. For example, referring to FIG. 3, source electrode 52 may be formed to cover the entire surface of interlayer insulating film 40. In this case, the plurality of adjacent source regions 15 and contact regions 16 can be electrically connected to each other by not only source interconnection 60 and but also source electrode 52. Further, in this case, first metal film etching step (S82) can be omitted.

Thus, also by using the semiconductor device and the method for manufacturing the semiconductor device in the present embodiment, there can be obtained effects similar to those of the semiconductor device and the method for manufacturing the semiconductor device in the first embodiment of the present invention.

### Third Embodiment

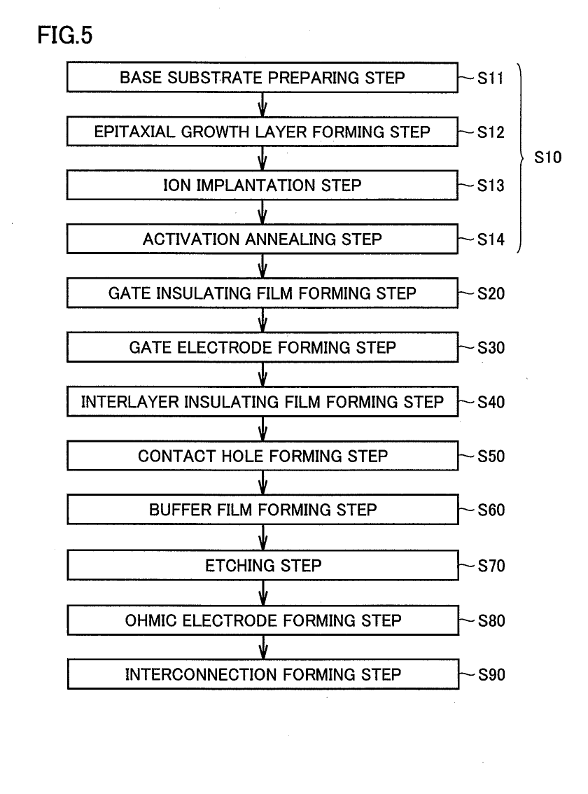

The following describes a semiconductor device and a method for manufacturing the semiconductor device in a third embodiment of the present invention. Referring to FIG. 4, the semiconductor device according to the present embodiment has basically the same configuration as that of the semiconductor device according to the first embodiment, but is different therefrom in that buffer film 51 has an end portion 51A formed on side wall surface 80A so as to be opposite to bottom surface 80B of contact hole 80, and that source electrode 52 has an end portion 52A formed on interlayer insulating film 40 so as to be closer to bottom surface 80B of contact hole 80 relative to end portion 51A of buffer film 51. In MOSFET 1 serving as the semiconductor device according to the present embodiment, buffer film 51 and source electrode 52 are not formed on upper surface 40A of interlayer insulating film 40.

Further, the method for manufacturing the semiconductor device in the present embodiment includes basically the same steps as those in the first embodiment, but is different therefrom in that in step (S70) of etching the buffer film, buffer film 51 is removed entirely from upper surface 40A of interlayer insulating film 40 and is partially removed from side wall surface 80A and bottom surface 80B of contact hole 80. Another difference lies in that in step (S82) of etching the first metal film, the end portion of the first metal film is formed to be closer to bottom surface 80B of contact hole 80 relative to end portion 51A of buffer film 51. Accordingly, even when Al contained in source electrode 52 is migrated in the alloying annealing step, Al can be suppressed from migrating beyond buffer film 51 and reacting with interlayer insulating film 40.

Thus, also by using the semiconductor device and the method for manufacturing the semiconductor device in the present embodiment, there can be obtained effects similar to those of the semiconductor device and the method for manufacturing the semiconductor device in the first embodiment of the present invention.

Further, in each of the above-described embodiments, in the case of an IGBT, an emitter electrode can be employed as an electrode having a function of supplying carriers, as with source electrode 52, for example.

The semiconductor device and the method for manufacturing the semiconductor device in the present invention is particularly advantageously applied to a semiconductor device required to suppress a reaction between an electrode containing aluminum and an insulating film, as well as a method for manufacturing such a semiconductor device.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a substrate made of silicon carbide;
an insulating film formed on a surface of said substrate;
a buffer film containing no Al; and
an electrode containing Al,
said substrate having an electrically conductive region,
a contact hole being formed above said electrically conductive region so as to extend through said insulating film and expose the surface of said substrate,
said buffer film extending upward on a side wall surface of said contact hole from a bottom surface of said contact hole,
said electrode being formed in contact with said electrically conductive region on said bottom surface of said contact hole, said electrode being formed on said insulating film with said buffer film being interposed therebetween.

2. The semiconductor device according to claim 1, wherein
said buffer film extends onto an upper surface of said insulating film via said side wall surface, and has an end portion formed on said upper surface of said insulating film, and
said electrode has an end portion formed on said insulating film so as to be closer to said contact hole relative to said end portion of said buffer film.

3. The semiconductor device according to claim 1, wherein
a plurality of said contact holes are formed, and
said buffer film extends from said bottom surface of one of the plurality of said contact holes to said bottom surface of another one of the plurality of said contact holes via an upper surface of said insulating film so as to cover a portion of said insulating film between adjacent ones of the plurality of said contact holes.

4. The semiconductor device according to claim 3, wherein said electrode on said insulating film is formed to cover an entire surface of said buffer film.

5. The semiconductor device according to claim 3, wherein said electrode on said insulating film is formed to cover a portion of said buffer film.

6. The semiconductor device according to claim 1, wherein
said buffer film has an end portion formed on said side wall surface and opposite to said bottom surface of said contact hole, and
said electrode has an end portion formed on said insulating film so as to be closer to said bottom surface of said contact hole relative to said end portion of said buffer film.

7. The semiconductor device according to claim 1, wherein said buffer film is made of TiN.

8. The semiconductor device according to claim 1, wherein said electrode is made of TiAlSi.

9. The semiconductor device according to claim 1, wherein said buffer film has a thickness of not less than 0.025 μm and not more than 0.15 μm.

10. A method for manufacturing a semiconductor device, comprising the steps of:
preparing a substrate made of silicon carbide;
forming an insulating film on a surface of said substrate;
forming a contact hole so as to extend through said insulating film and expose said surface of said substrate;
forming a buffer film containing no Al on a side wall surface of said contact hole; and
forming an electrode containing Al on and in contact with said surface of said substrate exposed by forming said contact hole, said electrode being formed on said insulating film with said buffer film being interposed therebetween.
